(19) United States
(12) Patent Application Publication
(10) Pub. No.: US 2026/0318751 A1
(43) Pub. Date: Oct. 15, 2026

(54) METHOD AND SYSTEM FOR ESTIMATING TEMPERATURE DISTRIBUTION IN BATTERIES, STORAGE MEDIUM, AND ELECTRONIC DEVICE

(71) Applicant: SHANDONG UNIVERSITY, Jinan (CN)

(72) Inventors: Yunlong SHANG, Jinan (CN); Xiaoqiang ZHANG, Jinan (CN); Yuhao ZHU, Jinan (CN); Linfei HOU, Jinan (CN); Jingyu HU, Jinan (CN); Miao YU, Jinan (CN)

(21) Appl. No.: 19/290,435

(22) Filed: Aug. 5, 2025

(30) Foreign Application Priority Data
Apr. 9, 2025 (CN) 202510436063X

(51) Int. Cl. G01K 3/14; G01K 1/02; G01K 11/32; G06F 30/17

(52) U.S. Cl. CPC G01K 3/14; G01K 1/026; G01K 11/32; G06F 30/17

(57) ABSTRACT

The present invention provides a method for estimating temperature distribution in a battery, comprising: obtaining and pre-processing distributed temperature data on a battery surface, performing spatial mapping on the pre-processed temperature data; constructing an electrochemical model for determining heat sources, constructing a geometric model based on battery morphological parameters, coupling the geometric model with the determined heat sources to form a battery thermal model; performing domain division on the battery thermal model based on temperature gradient differences to form a plurality of sub-domains, calibrating convective heat transfer coefficients of different sub-domains based on the spatial mapping results, and obtaining temperature distribution estimation results on the battery surface based on the calibrated convective heat transfer coefficients; and by reading local hotspots from the results, battery thermal management system controls flow rate of liquid coolant in regions to increase, or adjusts speed of air-cooling fans, thereby achieving regional differentiated thermal control.

### CROSS-REFERENCE TO RELATED APPLICATIONS

The present disclosure claims priority to Chinese Patent Application No. 202510436063.X, filed with the China National Intellectual Property Administration on Apr. 9, 2025, and entitled “Method and System for Estimating Temperature Distribution in Batteries, Storage Medium, and Electronic Device”, which is hereby incorporated by reference in its entirety and forms a part of the present disclosure for all purposes.

### TECHNICAL FIELD

The present disclosure belongs to the technical field of temperature distribution estimation, and specifically relates to a method and system for estimating temperature distribution in a battery, a storage medium, and an electronic device.

### BACKGROUND

The statement of this section merely provides background art information related to the present disclosure, and does not necessarily constitute the prior art.

In estimation of temperature distribution in a battery, conventional model-based estimation methods typically assume a uniform convective heat transfer coefficient across the surface of the battery. This simplified assumption ignores the potential non-uniformity of thermal flux on the surface of the battery, which can lead to a significant decrease in estimation accuracy. In addition, validation approaches of existing models, which mainly rely on temperature data from a limited number of thermocouple measurement points, fail to effectively reflect true temperature variations across the surface of a large-format battery or a three-dimensional battery.

Some studies provide the use of distributed multi-mode fibers in acquisition of temperature data from battery measurement points. However, the studies typically divide a battery module into different discrete zones, monitor the temperature of each zone, and compare the monitored temperature with a preset threshold. The analysis process is relatively simple and still falls within the scope of single-point temperature distribution estimation under the assumption of a uniform convective heat transfer coefficient across the surface of the battery.

In practical application, such as energy storage systems or electric vehicles, battery (such as lithium battery) cells and different regions of a battery interact with each other. During operation, electrochemical reactions occur inside the battery, resulting in non-uniform electric heat distribution. If the temperature of each region of the battery cannot be dynamically and accurately detected or accurately controlled, local overheating in the battery may occur. In addition, a mismatching thermal management strategy may trigger further reactions in the battery. Once this cascade starts, even a reinforced thermal management strategy may fail to suppress local overheating, ultimately leading to thermal runaway.

To sum up, in practical application, existing methods exhibit poor accuracy in estimating the temperature distribution in the battery. This issue is particularly evident during battery operation, where the spatial resolution and real-time monitoring capability of temperature on the surface of the battery fail to meet the requirements for efficient management and safety monitoring.

### SUMMARY

In order to solve the above problems, the present disclosure provides a method and system for estimating temperature distribution in a battery, a storage medium, and an electronic device. In the present disclosure, temperature is obtained through a distributed optical fiber sensor, optical fiber data is mapped to associate various positions on the surface of the battery, an electrochemical model and a thermal model are coupled, a convective heat transfer coefficient is calibrated in each region of the surface of the battery based on temperature gradient differences across different positions on the surface of the battery and the mapping results, and then accurate estimation/prediction of temperature distribution is implemented, thereby significantly improving the spatial resolution and real-time monitoring capability of temperature on the surface of the battery and effectively preventing battery thermal runaway.

According to some embodiments, the present disclosure adopts the following technical solutions.

A method for estimating temperature distribution in a battery, including the following steps:

obtaining distributed temperature data on the surface of a battery, pre-processing the temperature data, and performing spatial mapping on the pre-processed temperature data;

constructing an electrochemical model, determining heat sources, constructing a geometric model based on morphological parameters of the battery, and coupling the geometric model with the determined heat sources to form a battery thermal model; and

performing domain division on the battery thermal model based on temperature gradient differences across different positions to form a plurality of sub-domains, calibrating convective heat transfer coefficients of different sub-domains based on the spatial mapping results, and obtaining temperature distribution estimation results on the surface of the battery based on the calibrated convective heat transfer coefficients.

As an optional implementation, in the process of obtaining distributed temperature data on the surface of a battery, optical fiber data is obtained by using distributed optical fiber sensors, where the distributed optical fiber sensors are arranged on the surface of the battery in a reciprocating pattern, or at intervals in a helical pattern, or at intervals in a grid pattern; and

the distributed optical fiber sensors are provided within designated positive and negative electrode regions of the battery, or/and within a designated central region of the battery.

As an optional implementation, the pre-processing process includes: converting wavelength data of the optical fiber into temperature data based on a relationship between a frequency shift induced by Rayleigh scattering and temperature; or,

further comparing the converted temperature data with temperature data detected by a temperature sensor at a corresponding position to obtain an accurate wavelength-temperature relationship equation, and calibrating the converted temperature data.

As an optional implementation, the process of performing spatial mapping on the pre-processed optical fiber data includes: dividing an arrangement path of the optical fiber into a plurality of segments, where each segment is a straight segment or an arc segment, and end points and/or center points of the segments are used as feature points to calibrate key positions of the path of the optical fiber;

for the straight segment, uniformly mapping all optical fiber data within the straight segment onto the straight segment by using an interpolation algorithm; and

for the arc segment, determining a center angle and radius of the arc segment, calculating distribution of the optical fiber within the arc segment by using an arc length formula, and uniformly mapping all optical fiber data within the arc segment onto the corresponding arc path on the surface of the battery according to an arc length proportion by using the interpolation algorithm.

As an optional implementation, the process of performing spatial mapping on the pre-processed optical fiber data includes: when the distributed optical fiber sensors are arranged in the helical pattern, determining basic parameters of the helix, including a radius of a projection circle of the helix on a horizontal plane, a pitch, and a total length of the helix; and calculating parameter equations of the helix, calculating an arc length of the helix by integration, then determining an arc length corresponding to each data point, and performing reverse calculation to determine three-dimensional coordinates of the data point on the helix.

As an optional implementation, the process of constructing an electrochemical model includes: selecting to construct a one-dimensional, two-dimensional, or three-dimensional electrochemical model according to an actual usage scenario and performance requirements of the battery, where the electrochemical model is used to calculate heat generated by the battery during charging and discharging based on the type of the battery and the electrochemical reaction process, ion transport characteristics, and the law of charge conduction inside the battery, and the generated heat includes Ohmic heat, activation heat, reaction heat, and tab generated heat.

As an optional implementation, the process of constructing a geometric model based on morphological parameters of the battery includes: constructing the geometric model of the battery by three-dimensional modeling based on the actual dimensions and morphology of the battery, where the geometric model is used to reflect the external dimensions, internal structure, and surface morphological characteristics of the battery.

As an optional implementation, the process of performing domain division on the battery thermal model based on temperature gradient differences across different positions to form a plurality of sub-domains includes: dividing the surface of the battery into the plurality of sub-domains based on horizontal and vertical temperature gradients on the surface of the battery and requirements for model accuracy, where each sub-domain corresponds to a different convective heat transfer coefficient to reflect dynamic characteristics of heat exchange between different regions of the battery, and the heat exchange between each sub-domain and the environment can be individually configured.

As an optional implementation, the process of calibrating convective heat transfer coefficients of different sub-domains based on the spatial mapping results includes: comparing temperature data obtained from the optical fiber data of different sub-domains with calculation results of the battery thermal model, and adjusting and optimizing the convective heat transfer coefficients of the corresponding sub-domains based on the differences.

As an optional implementation, the process of calibrating convective heat transfer coefficients of different sub-domains includes: simulating a cooling process by using the battery thermal model based on temperature variations across the battery recorded by the distributed optical fiber sensors, and determining initial values of the convective heat transfer coefficients by matching experimental temperature decay curves; and

performing iterative optimization by taking minimization of a squared difference between the temperature distribution predicted by the model and the obtained true value as an objective function to adjust the convective heat transfer coefficients until the temperature distribution predicted by the model converges within a preset threshold.

A system for estimating temperature distribution in a battery includes:
a temperature obtaining module, configured to obtain distributed temperature data on the surface of a battery, pre-process the temperature data, and perform spatial mapping on the pre-processed temperature data;
a coupled model constructing module, configured to construct an electrochemical model, determine heat sources, construct a geometric model based on morphological parameters of the battery, and couple the geometric model with the determined heat sources to form a battery thermal model; and
a temperature distribution estimating module, configured to perform domain division on the battery thermal model based on temperature gradient differences across different positions to form a plurality of sub-domains, calibrate convective heat transfer coefficients of different sub-domains based on spatial mapping results, and obtain temperature distribution estimation results on the surface of the battery based on the calibrated convective heat transfer coefficients.

A computer-readable storage medium is used for storing computer-readable instructions that, when executed by a processor, complete the steps of the aforementioned method.

A computer program product includes computer-readable instructions that, when executed by at least one data processing apparatus, enable the data processing apparatus to implement the steps of the aforementioned method.

An electronic device includes a memory, a processor, and computer-readable instructions stored on the memory and executed on the processor, where the computer-readable instructions, when executed by the processor, enable the processor to complete the steps of the aforementioned method.

An electric vehicle includes a vehicle body, the vehicle body including a battery, distributed optical fiber sensors, and a battery management system, wherein:
the battery is used to provide energy for the electric vehicle;
the distributed optical fiber sensors are used to obtain optical fiber data; and
the battery management system is used to pre-process the optical fiber data, and
perform spatial mapping on the pre-processed optical fiber data;
construct an electrochemical model, determine heat sources, construct a geometric model based on morphological parameters of the battery, and couple the geometric model with the determined heat sources to form a battery thermal model; and
perform domain division on the battery thermal model based on temperature gradient differences across different positions to form a plurality of sub-domains, calibrate convective heat transfer coefficients of different sub-domains based on the spatial mapping results, and obtain temperature distribution estimation results on the surface of the battery based on the calibrated convective heat transfer coefficients;
or, the battery management system includes the aforementioned system for estimating temperature distribution in a battery;

or, the battery management system is loaded with the aforementioned computer-readable storage medium;

or, the battery management system includes the aforementioned electronic device.

Compared with the prior art, the present disclosure achieves the following beneficial effects:
The present disclosure uses the distributed optical fiber sensors to dynamically obtain the temperature on the surface of the battery, the optical fiber can uniformly cover key regions on the surface of the battery to obtain comprehensive and continuous temperature information, and the arrangement scheme can be flexibly determined based on the shape and dimensions of the battery and the thermo-physical characteristics in key temperature monitoring regions.

The present disclosure uses a feature point positioning method and a spatial mapping algorithm to accurately map one-dimensional temperature data collected by the optical fiber to a two-dimensional plane/three-dimensional space of the battery, thereby achieving accurate spatial mapping of battery temperature, and showing the temperature in different regions more accurately and intuitively during battery thermal management.

The present disclosure can flexibly select to construct the one-dimensional, two-dimensional, or three-dimensional electrochemical model based on the actual usage scenario and performance requirements of the battery, and fully consider the electrochemical reaction processes, ion transport characteristics, and the law of charge conduction inside the battery, thereby accurately calculating heat generated by the battery during charging and discharging, providing heat source data, and ensuring the accuracy of subsequent thermal management.

By constructing the battery thermal model with multi-domain convective heat boundaries, the present disclosure fully considers the processes such as heat generation and heat conduction within the battery and heat exchange with the external environment, can truly reflect the law of heat transfer in the battery during operation, and improves the prediction accuracy of the model based on multi-domain division.

By adjusting and optimizing the convective heat transfer coefficient of each sub-domain, the present disclosure considers potential non-uniformity of thermal flux on the surface of the battery, whereby the predicted temperature distribution meets accuracy requirements.

The present disclosure has a wide application range, and can be applied to both power batteries and energy storage batteries. In practical application, the present disclosure can dynamically monitor the temperature in various regions, especially key regions, on the surface of the battery in a timely manner, and can help to correct the thermal management strategy in a timely manner, thereby improving the thermal management effect of the battery and effectively preventing thermal runaway of the battery.

In order to make the above objectives, features, and advantages of the present disclosure more obvious and understandable, preferred embodiments are provided below and combined with accompanying drawings for detailed description as follows.

### BRIEF DESCRIPTION OF THE DRAWINGS

Accompanying drawings forming a part of the present disclosure are used for providing a further understanding of the present disclosure, and schematic embodiments of the present disclosure and descriptions thereof are used for interpreting the present disclosure, rather than forming improper limitations on the present disclosure.

FIG. 1 is a schematic flowchart of a method for estimating temperature distribution in a battery according to one of examples;

FIG. 2 is a schematic diagram of an arrangement scheme of distributed optical fiber sensors for a pouch battery according to one of examples;

FIG. 3 is a schematic diagram of an arrangement scheme of distributed optical fiber sensors for a cylindrical battery according to one of examples;

FIG. 4A is a schematic diagram of an arrangement scheme of distributed optical fiber sensors for a prismatic battery according to one of examples;

FIG. 4B is a schematic diagram of an arrangement scheme of distributed optical fiber sensors for a battery pack according to one of examples;

FIG. 5 is a schematic diagram of spatial mapping feature points of an S-shaped optical fiber arrangement scheme according to one of examples;

FIG. 6 is a physical diagram of an S-shaped arrangement of distributed optical fiber sensors for a pouch battery according to one of examples;

FIG. 7A shows temperature data obtained by thermocouples and an optical fiber during 0.5C charging and discharging according to one of examples;

FIG. 7B shows voltage and current data during 0.5C charging and discharging according to one of examples;

FIG. 8A shows temperature data obtained by thermocouples and an optical fiber during 1C charging and discharging according to one of examples;

FIG. 8B shows voltage and current data during 1C charging and discharging according to one of examples;

FIG. 9A shows temperature data obtained by thermocouples and an optical fiber during 1.25C charging and discharging according to one of examples;

FIG. 9B shows voltage and current data during 1.25C charging and discharging according to one of examples;

FIG. 10A shows temperature data obtained by thermocouples and an optical fiber during 1.5C charging and discharging according to one of examples;

FIG. 10B shows voltage and current data during 1.5C charging and discharging according to one of examples;

FIG. 11A is a schematic diagram of temperature distribution in a battery during 1C discharging when SOC=1.0 according to one of examples;

FIG. 11B is a schematic diagram of temperature distribution in a battery during 1C discharging when SOC=0.9 according to one of examples;

FIG. 11C is a schematic diagram of temperature distribution in a battery during 1C discharging when SOC=0.8 according to one of examples;

FIG. 11D is a schematic diagram of temperature distribution in a battery during 1C discharging when SOC=0.7 according to one of examples;

FIG. 11E is a schematic diagram of temperature distribution in a battery during 1C discharging when SOC=0.6 according to one of examples;

FIG. 11F is a schematic diagram of temperature distribution in a battery during 1C discharging when SOC=0.5 according to one of examples;

FIG. 11G is a schematic diagram of temperature distribution in a battery during 1C discharging when SOC=0.4 according to one of examples;

FIG. 11H is a schematic diagram of temperature distribution in a battery during 1C discharging when SOC=0.3 according to one of examples;

FIG. 11I is a schematic diagram of temperature distribution in a battery during 1C discharging when SOC=0.2 according to one of examples;

FIG. 11J is a schematic diagram of temperature distribution in a battery during 1C discharging when SOC=0.1 according to one of examples;

FIG. 12 is a schematic diagram of a three-dimensional geometric model of a battery according to one of examples;

FIG. 13 is a schematic diagram of multi-domain thermal boundaries according to one of examples;

FIG. 14 is a schematic diagram of positions of 5 representative temperature points according to one of examples;

FIG. 15 shows a comparison between model predicted temperature curves and optical fiber monitored temperature curves according to one of examples;

FIG. 16A is a schematic diagram of model predicted battery temperature distribution when SOC=1.0 according to one of examples;

FIG. 16B is a schematic diagram of model predicted battery temperature distribution when SOC=0.8 according to one of examples;

FIG. 16C is a schematic diagram of model predicted battery temperature distribution when SOC=0.6 according to one of examples;

FIG. 16D is a schematic diagram of model predicted battery temperature distribution when SOC=0.4 according to one of examples;

FIG. 16E is a schematic diagram of model predicted battery temperature distribution when SOC=0.2 according to one of examples;

FIG. 16F is a schematic diagram of model predicted battery temperature distribution when SOC=0 according to one of examples; and

FIG. 17 is a schematic diagram of an electronic device according to one of examples.

### DETAILED DESCRIPTION

The present disclosure will be further described below in conjunction with the accompanying drawings and embodiments.

It should be pointed out that the following detailed descriptions are all exemplary and aim to further illustrate the present disclosure. Unless otherwise specified, all technological and scientific terms used herein have the same meanings generally understood by those of ordinary skill in the technical field of the present disclosure.

It should be noted that the terms used herein are merely for describing specific implementations, but are not intended to limit exemplary implementations according to the present disclosure. As used herein, unless otherwise clearly stated in the context, a singular form is also intended to include a plural form. In addition, it should also be understood that, when the terms “include” and/or “comprise” are used in the specification, they indicate features, steps, operations, devices, components, and/or combinations thereof.

It should be noted that the embodiments in the present disclosure and the features in the embodiments can be combined with each other without conflicts.

### Example 1

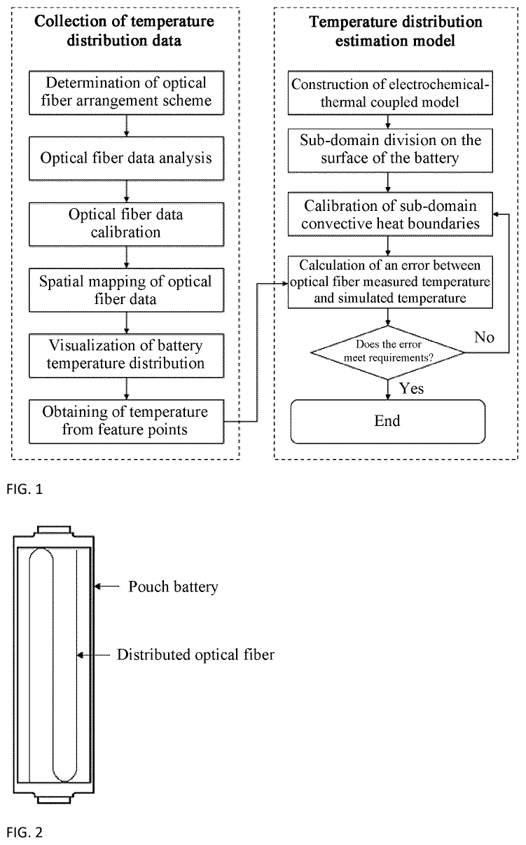

A method for estimating temperature distribution in a battery, as shown in FIG. 1, includes the following steps:
S1: obtain distributed temperature data on the surface of a battery, pre-process the temperature data, and perform spatial mapping on the pre-processed temperature data;
S2: construct an electrochemical model, determine heat sources, construct a geometric model based on morphological parameters of the battery, and couple the geometric model with the determined heat sources to form a battery thermal model; and
S3: perform domain division on the battery thermal model based on temperature gradient differences across different positions to form a plurality of sub-domains, calibrate convective heat transfer coefficients of different sub-domains based on the spatial mapping results, and obtain temperature distribution estimation results on the surface of the battery based on the calibrated convective heat transfer coefficients.

It should be noted that the battery generally refers to an electrochemical battery, such as a lithium-ion battery.

Details of each step will be elaborated below.

Firstly, optical fiber data is obtained.

In the present example, the optical fiber data is obtained through distributed optical fiber sensors. In the present example, the arrangement scheme of the distributed optical fiber sensors is not limited, but can be flexibly designed based on the shape and dimensions of the battery and thermo-physical characteristics in key temperature monitoring regions.

For different batteries, the arrangement scheme is considered acceptable as long as it can meet the requirements of temperature distribution monitoring, namely, ensuring that an optical fiber can uniformly cover key regions on the surface of the battery to obtain comprehensive and continuous temperature information.

To make those skilled in the art understand the solution of the present example more clearly, the following arrangement schemes are listed.

As shown in FIG. 2, in practical application, for a prismatic pouch battery or a battery with a surface dimensions exceeding a preset value, an S-shaped arrangement scheme or other continuous arrangement schemes of reciprocating bending shapes, such as a zigzag shape and a W shape, may be adopted, and will not be exhausted here.

For each type of battery, the spacing and bending amplitude of the reciprocating bending shape can be reasonably adjusted in advance through finite element simulation or experimental analysis, whereby the optical fiber can effectively cover key regions on the surface of the battery, such as high heat emission regions of the battery near positive and negative electrodes and a central region of the battery where the heat dissipation is difficult, thereby obtaining comprehensive and representative temperature data.

For cylindrical batteries or other circular batteries, the optical fiber can be arranged in a helical winding manner to uniformly cover the cylindrical surface of the battery, so as to obtain temperature variations in both circumferential and axial directions of the battery.

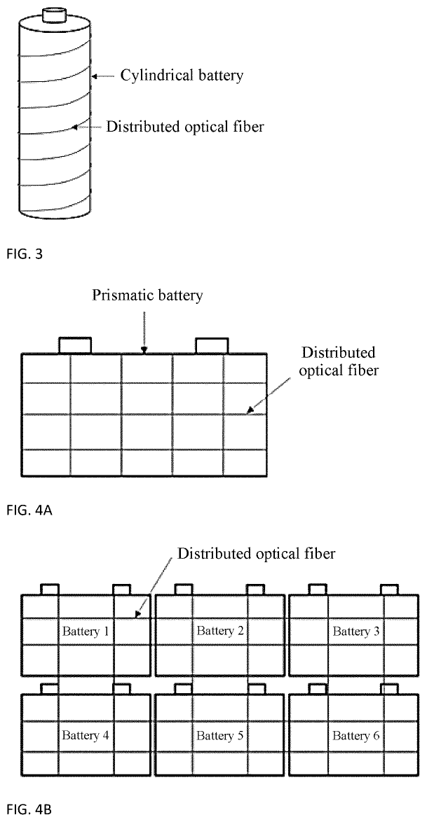

As shown in FIG. 3, by helically winding the optical fiber, temperature differences across the battery at different heights and circumferential positions can be captured to provide accurate data support for the optimization of a battery thermal management system.

Similarly, the spacing and bending amplitude of the helix can be reasonably determined in advance through finite element simulation or experimental analysis, whereby the optical fiber can effectively cover key regions on the surface of the battery or obtained temperature results are more reasonable.

For batteries with large surface area, prismatic batteries or battery modules, a grid-like arrangement can also be adopted to fully exert the monitoring efficiency of the distributed optical fiber sensors.

As shown in FIG. 4A and FIG. 4B, a crisscross optical fiber network is constructed on the surface of a battery cell or battery pack. By using the spatial division characteristics of a grid structure, temperature variations across different regions on the surface of the battery can be accurately captured. This arrangement achieves regular region division on the surface of the battery, thereby greatly facilitating subsequent analysis and processing of temperature data in different regions.

Similarly, the size and spacing of the network can be reasonably determined in advance through finite element simulation or experimental analysis, whereby the optical fiber can effectively cover key regions on the surface of the battery or obtained temperature results are more reasonable.

In other embodiments, the distributed optical fiber sensors may be arranged in other shapes, following the overall principle that the optical fiber can cover the entire surface of the battery at intervals. In addition, the simpler and more regular shape is more beneficial to later mapping.

Similarly, in some other embodiments, the distributed optical fiber sensors may be arranged at an equal interval or different intervals; or the optical fiber may have bending portions or be arranged straight.

Next, the pre-processing is performed.

In the present example, the pre-processing refers to accurate conversion of wavelength data collected by the distributed optical fiber sensors into temperature data through a standard calibration process, including optical fiber data analysis and calibration.

Firstly, the optical fiber data analysis aims to accurately convert a physical relationship between wavelength data collected by the distributed optical fiber sensors and temperature variations. The temperature measurement of an optical fiber sensor usually relies on light scattering effects (such as Brillouin scattering, Raman scattering, and Rayleigh scattering) in the optical fiber. These scattering effects induce frequency shifts in the optical fiber, and there is a clear relationship between frequency shifts and temperature variations.

Taking Rayleigh scattering as an example, in the optical fiber sensor, temperature variations may lead to a frequency shift in Rayleigh scattering signals in the optical fiber. The frequency shift has a linear relationship with the temperature variations inside the optical fiber. By measuring this frequency shift, the temperatures of different sensing units of the optical fiber can be calculated. Specifically, the relationship between the frequency shift induced by Rayleigh scattering and the temperature can be expressed by the following equation:

$$\frac{Δ λ}{{λ}_{0}} = {K}_{T} Δ T + {K}_{s} Δ ε , \qquad ( 1 )$$

wherein, Δλ denotes a Rayleigh scattering-induced frequency shift, 7% denotes a center wavelength of the optical fiber, K_{T} and K_{S} denote sensitivity coefficients of temperature and strain respectively, indicating the influence of temperature and strain variations on the scattering wavelength of the optical fiber, and ΔT and Δε denote variations of temperature and strain respectively.

The optical fiber sensor coated with perfluoroalkoxy resin shields the influence of strain on the scattering wavelength of the optical fiber, so the relationship between the frequency shift induced by Rayleigh scattering and the temperature can be expressed as follows:

$$\frac{Δ λ}{{λ}_{0}} = {K}_{T} Δ T . \qquad ( 2 )$$

In other examples, other existing algorithms can be selected for temperature data conversion based on the type of the distributed optical fiber sensor. For example, for an optical frequency domain reflectometry-based distributed optical fiber sensor, the temperature at a corresponding position can be calculated by comparing local reference signals with measurement signals and using spectra determined by the light scattering effect. Details are not repeated here.

Then, optical fiber measurement results need to be calibrated. The measurement results of the optical fiber sensor may be affected by environmental factors, optical fiber arrangement, and material differences, so these deviations need to be eliminated through a calibration process.

In the present example, the specific steps of calibration are as follows: the optical fiber sensor is compared with a high-precision temperature sensor (such as a thermocouple) to obtain an accurate wavelength-temperature relationship equation, that is, to determine K_{T} in equation (2).

Next, the spatial mapping is performed on the optical fiber data. The objective of this step is to accurately map one-dimensional temperature data collected by the optical fiber sensors to a two-dimensional plane/three-dimensional space of the battery through an accurate spatial mapping algorithm.

The present example employs a feature point-based spatial mapping algorithm. As shown in FIG. 5, taking an S-shaped optical fiber arrangement as an example, the feature point-based spatial mapping algorithm includes the following specific process.

(1) A path of the optical fiber, arranged in an S shape, includes a plurality of straight segments and arc segments, and key positions of the path of the optical fiber are calibrated through feature points (such as A, B, C, D, E, F, G, and H). The coordinates of these feature points are used to determine an arrangement path of the optical fiber and provide a stable reference for subsequent mapping.

(2) For the straight segment, taking a segment AB as an example, firstly, actual optical fiber lengths L_{A} and L_{B} corresponding to a point A and a point B need to be determined. Then, data in the interval [L_{A}, L_{B}] is extracted and saved to a separate file. Further, all measurement point data of the optical fiber within the range of L_{A} and L_{B} are uniformly mapped to the segment AB by using an interpolation algorithm. Specifically, each sensing unit data between L_{A} and L_{B} is proportionally converted into corresponding coordinates on the segment AB based on the relative position of its optical fiber length in the interval [L_{A}, L_{B}] by using a linear interpolation algorithm.

For other straight segments, this method is also applicable. This method can ensure accurate mapping of temperature data within each straight segment to the surface of the battery, thereby providing precise data support for subsequent temperature distribution estimation.

(3) For the arc segment, firstly, a center angle and radius of the arc segment are determined, and the distribution of the optical fiber within the arc segment is calculated by using an arc length formula. Then, all optical fiber sensing unit data within the arc segment are uniformly distributed according to an arc length proportion by using the interpolation algorithm, thereby ensuring that each measurement point data can be accurately mapped to a corresponding arc path on the surface of the battery.

Through the above steps, the data from each sensing unit of the optical fiber can be accurately spatially mapped to the two-dimensional plane of the battery.

For the helical arrangement scheme shown in FIG. 3, its data mapping scheme is as follows:
(1) Determine basic parameters of the helix

The basic parameters include: a radius r of a projection circle of the helix on a horizontal plane; a height by which the helix rises in a vertical direction after each rotation, namely, a pitch p; and a total length L of the helix.
(2) Calculate parameter equations of the helix

The helix can be represented by parameter equations as follows:

x(t)=r cos(t),

y(t)=r sin(t),

$$z ( t ) = \frac{p}{2 π} t ,$$

wherein, t denotes a parameter, usually within a range of [0, 2πn], and n denotes the number of rotations of the helix.
(3) Perform data mapping
(a) An arc length s(t) of the helix can be calculated by integration:

$$s ( t ) = {\int }_{0}^{t} \sqrt{{( \frac{dx}{dt} )}^{2} + {( \frac{dy}{dt} )}^{2} + {( \frac{dz}{dt} )}^{2}} dt .$$

The above parameter equation can be simplified as follows:

$$s ( t ) = t \sqrt{{r}^{2} + {( \frac{p}{2 π} )}^{2}} .$$

(b) Assuming that the total length of the optical fiber is L, the arc length corresponding to each data point is as follows:

$${s}_{i} = \frac{i}{N} L .$$

By reverse calculation, the corresponding parameter tᵢ is determined:

$${t}_{i} = \frac{{s}_{i}}{\sqrt{{r}^{2} + {( \frac{p}{2 π} )}^{2}}} .$$

Then, tᵢ is substituted into the parameter equations of the helix to obtain three-dimensional coordinates:

xᵢ=r cos(tᵢ);

yᵢ=r sin(tᵢ);

$${z}_{i} = \frac{p}{2 π} {t}_{i} .$$

Finally, each data on the optical fiber is mapped to a three-dimensional coordinate (xᵢ, yᵢ, zᵢ) on the helix.

Then, the electrochemical model of the battery is constructed.

In the present example, a one-dimensional, two-dimensional, or three-dimensional electrochemical model can be flexibly constructed based on an actual usage scenario and performance requirements of the battery.

The one-dimensional model mainly considers the diffusion and reaction of lithium ions in the thickness direction of electrodes, while the two-dimensional and three-dimensional models may consider the distribution of lithium ions on an electrode plane and in space. By solving electrochemical equations, parameters, such as the potential, current density, and lithium-ion concentration, of the battery can be obtained to predict the performance and lifespan of the battery.

The one-dimensional model is suitable for quick simulation and analysis, especially for preliminary design and optimization stages, and can quickly obtain results for easy design and debug.

The two-dimensional model is suitable for scenarios that require high-precision simulation, such as design and optimization of a battery management system, and can provide more accurate internal information of the battery, making it suitable for situations with high requirements for battery performance.

The electrochemical model fully considers the electrochemical reaction process, ion transport characteristics, and the law of charge conduction inside the battery, and can accurately calculate heat generated by the battery during charging and discharging, thereby providing heat source data for subsequent construction of the battery thermal model.

The process of constructing an electrochemical model and the process of calculating heat sources can be implemented by existing solutions, and will not be further introduced here.

Based on the actual dimensions and morphology of the battery, a fine geometric model of the battery is constructed by using three-dimensional modeling technology. The model accurately reflects the external dimensions, internal structure, and surface morphological characteristics of the battery, thereby providing a foundation for subsequent thermal analysis.

Based on the law of energy conservation and combined with the heat sources calculated by the electrochemical model constructed above, the battery thermal model is constructed. The thermal model fully considers the processes such as heat generation and heat conduction within the battery and heat exchange with the external environment, and can truly reflect the law of heat transfer in the battery during operation.

Then, in consideration of the temperature gradient differences across different positions on the surface of the battery, the domain division is further performed on the surface of the battery.

In the present example, the surface of the battery is divided into a plurality of sub-domains based on the horizontal and vertical temperature gradients on the surface of the battery and the requirements for model accuracy. Through the domain division, the heat exchange between different regions and the environment can be individually configured, thereby improving the prediction accuracy of the thermal model.

Based on the sub-domains divided on the surface of the battery, the convective heat transfer coefficients of different sub-domains are calibrated with the temperature distribution data collected by the distributed optical fiber sensors.

Specifically, in the present example, the convective heat transfer coefficients are determined based on inverse identification of finite element parameters. Initial values of the convective heat transfer coefficients are estimated based on the natural cooling behavior of the battery, where temperature variations are recorded by the distributed optical fiber sensors. Then, the cooling process is simulated by using the thermal model, and the initial values of the convective heat transfer coefficients are determined by matching simulated and experimental temperature decay curves.

In order to further optimize the convective heat transfer coefficients, an iterative parameter identification process is implemented. This optimization process minimizes differences between the temperature distribution predicted by the model and optical fiber measurement values, and an objective function is defined as follows:

$$Φ ( h ) = {\sum }_{i = 1}^{N} {( {T}_{sim , i} ( h ) - {T}_{ex p , i} )}^{2} ,$$

wherein, T_{sim,i} denotes a simulated temperature at the measurement point i, while T_{exp,i} denotes an experimental temperature obtained from the distributed optical fiber sensor.

In the present example, a Levenberg-Marquardt algorithm is used to iteratively adjust the convective heat transfer coefficients until the temperature distribution predicted by the model converges within an acceptable error range of the experimental data.

### Example 2

In order to make those skilled in the art be clearer about the implementation of the technical solutions of the present disclosure, the present example is provided as a specific application example for description.

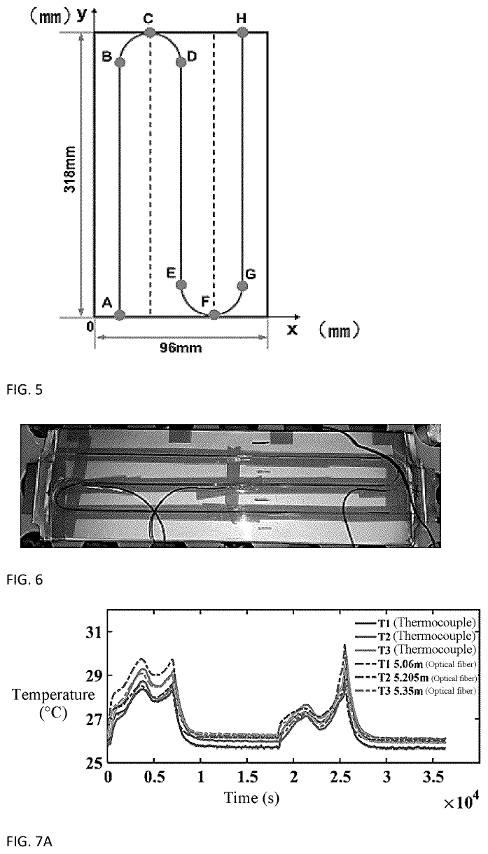

The present example takes a 318 mm×96 mm×12 mm pouch battery as an example. The battery is a ternary lithium-ion battery with a nominal capacity of 80.4 Ah. As shown in FIG. 6, the distributed optical fiber sensors are arranged in an S shape, and thermocouples are arranged at positive and negative electrode tabs of the battery and a central position of the battery for subsequent optical fiber data calibration.

The battery is charged and discharged at different rates, such as 0.5C, 1C, and 1.5C here. The charging and discharging conditions include constant current discharging, constant current and constant voltage charging, and standing for 3 hours after the discharging and charging are completed. Battery voltage, current, and thermocouple temperature data are collected and stored during charging and discharging. At the same time, the wavelength data of the optical fiber is collected and stored.

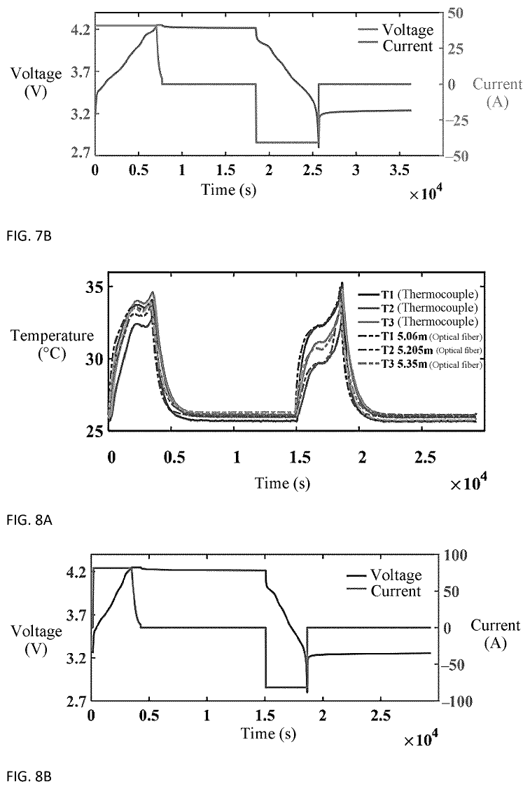

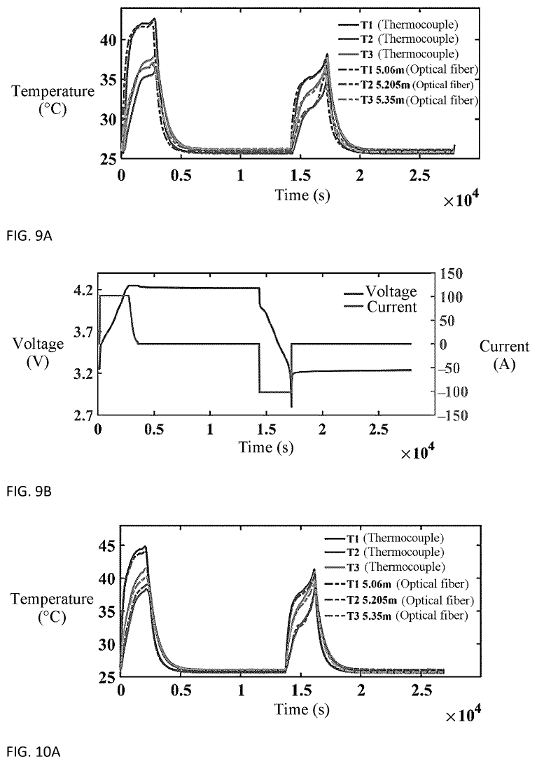

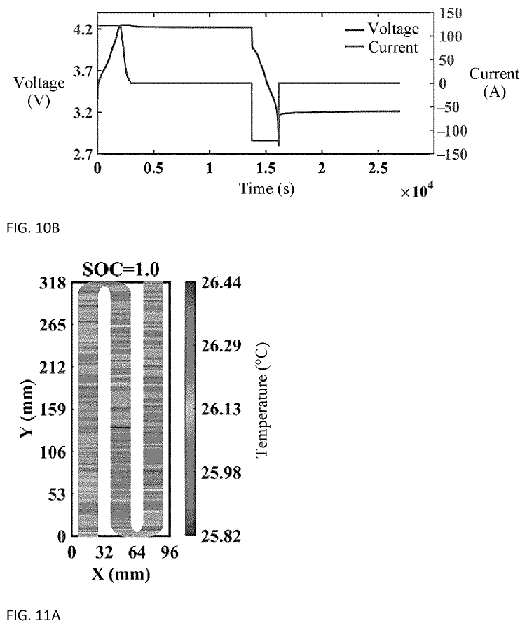

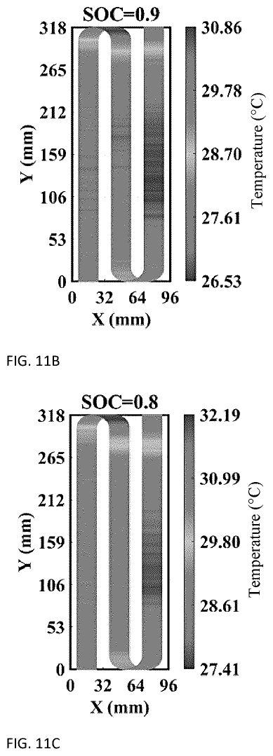

Based on the thermocouple data, the coefficients in equation (2) are calibrated to obtain accurate temperature data based on optical fiber measurements. In the present example, the coefficients λ₀·K_{T}=11.5 in equation (2). As shown in FIG. 7 to FIG. 10, FIG. 7A, FIG. 8A, FIG. 9A, and FIG. 10A respectively show optical fiber temperature data converted based on equation (2) and thermocouple temperature data at 0.5C, 1C, 1.25C, and 1.5C, while FIG. 7B, FIG. 8B, FIG. 9B, and FIG. 10B respectively show battery voltage and current data at 0.5C, 1C, 1.25C, and 1.5C. It can be seen that the calibrated temperature data is highly consistent with the thermocouple data.

By using the feature point-based spatial mapping algorithm, one-dimensional optical fiber data is mapped onto the two-dimensional surface of the battery. As shown in FIG. 5, the S-shaped optical fiber is divided into five segments: a straight segment AB, an arc segment BCD, a straight segment DE, an arc segment EFG, and a straight segment GH. The segments include 8 feature points (A, B, C, D, E, F, G, H) used for positioning, and the coordinates of each feature point are shown in Table 1.

Firstly, a path of the optical fiber on the two-dimensional plane can be determined through the coordinates in Table 1. Then, based on the actual lengths corresponding to respective optical fiber segments in Table 2, the fiber data of each segment is extracted separately and stored in a file. Finally, all data points contained in the respective segments are uniformly mapped to the aforementioned five-segment path by using the interpolation algorithm, thereby completing the mapping from the one-dimensional data to the two-dimensional space.

It should be noted that the spatial resolution of data of each segment can be configured according to accuracy requirements. The spatial resolution of the optical fiber in the present example is 1.28 mm. That is, there is a sensing unit every 1.28 mm among the aforementioned straight segment AB, arc segment BCD, straight segment DE, arc segment EFG, and straight segment GH.

TABLE 1
Coordinates of feature points

| Feature point | A | B | C | D |
|---|---|---|---|---|
| Coordinates | (16, 0) | (16, 302) | (32, 318) | (48, 302) |
| Feature point | E | F | G | H |
| Coordinates | (48, 16) | (64, 0) | (80, 16) | (80, 318) |

TABLE 2
Actual lengths of the optical fiber corresponding to
respective segments of the path

| Path | A → B | B → C → D | D → E | E → F → G | G → H |
|---|---|---|---|---|---|
| Length/ | (4.72, | (5.02, | (5.06, | (5.35, | (5.39, |
| m | 5.02) | 5.06) | 5.35) | 5.39) | 5.685) |

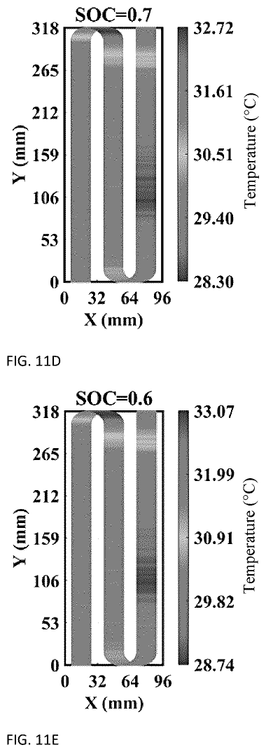

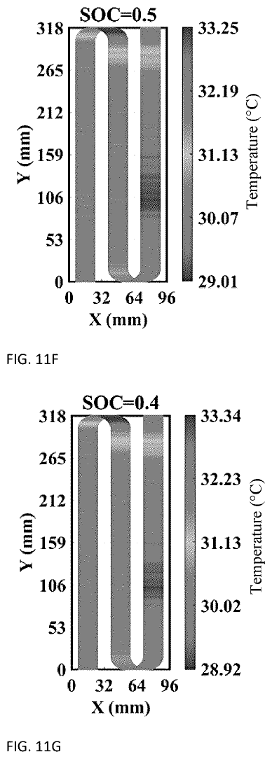

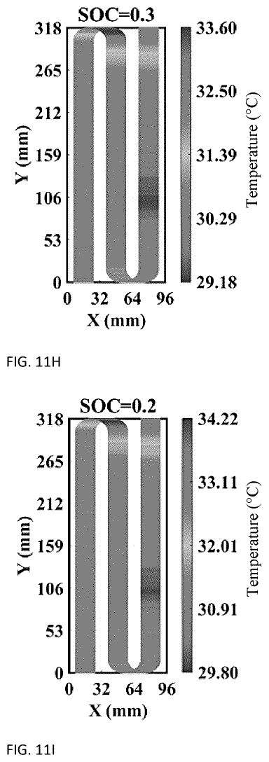

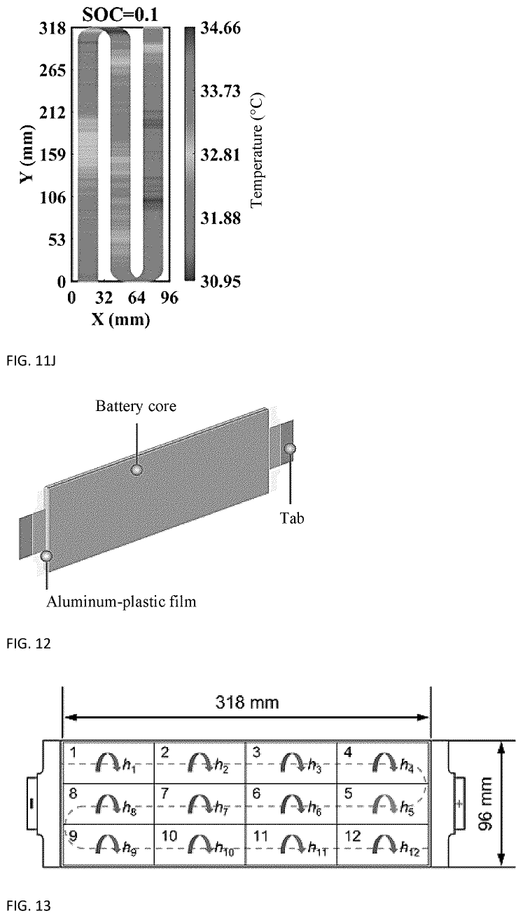

After the above steps are completed, temperature distribution maps as shown in FIG. 11A to FIG. 11J can be obtained, showing temperature distribution on the surface of a battery corresponding to different states of charge (SOCs) during 1C discharging. FIG. 11A shows temperature distribution in a battery at SOC=1.0, FIG. 11B shows temperature distribution in a battery at SOC=0.9, FIG. 11C shows temperature distribution in a battery at SOC=0.8, FIG. 11D shows temperature distribution in a battery at SOC=0.7, FIG. 11E shows temperature distribution in a battery at SOC=0.6, FIG. 11F shows temperature distribution in a battery at SOC=0.5, FIG. 11G shows temperature distribution in a battery at SOC=0.4, FIG. 11H shows temperature distribution in a battery at SOC=0.3, FIG. 11I shows temperature distribution in a battery at SOC=0.2, and FIG. 11J shows temperature distribution in a battery at SOC=0.1. So far, accurate analysis and two-dimensional visualization of the optical fiber data have been achieved.

Further, the electrochemical model of the battery is constructed. The present example employs a 1-dimensional pseudo two-dimensional (P2D) model, and relevant governing equations and boundary conditions are as follows. The electrochemical model can provide the heat sources for the thermal model, including Ohmic heat, activation heat, reaction heat, and tab generated heat.

The governing equation for charge conservation is as follows:

$$∇ \cdot ( - {σ}_{s}^{eff} ∇ {ϕ}_{s} ) = - {S}_{a} {i}_{loc} ; \qquad ( 3 )$$

wherein,

$${S}_{a} = 3 \times {ε}_{s} / {R}_{p} , {σ}_{s}^{eff} = {σ}_{s} {ε}_{s}^{{γ}_{s}} , \qquad ( 4 )$$

$$∇ \cdot ( - {σ}_{e}^{eff} ∇ {ϕ}_{e} + \frac{2 R T {σ}_{e}^{eff}}{F} ( 1 + \frac{\partial ln {f}_{\pm }}{\partial ln {c}_{e}} ) ( 1 - {t}_{+} ) ∇ ( ln {c}_{e} ) ) = {S}_{a} {i}_{loc} , \qquad ( 5 )$$

$${σ}_{e}^{eff} = {σ}_{e} {ε}_{e}^{{γ}_{e}} , \qquad ( 6 )$$

wherein,

$${σ}_{s}^{eff}$$

denotes a solid-phase effective conductivity, φₛ denotes a solid-phase potential, εₛ denotes a solid-phase volume fraction, Rₚ denotes a particle radius, cₑ denotes an electrolyte concentration, i_{loc} denotes a local current density, Sₐ denotes a specific surface area, γₛ denotes a solid-phase Bruggeman coefficient, σₛ denotes a solid-phase conductivity, ∇ denotes a vector differential operator,

$${σ}_{e}^{eff}$$

denotes a liquid-phase effective conductivity, R denotes a gas constant, T denotes a temperature, F denotes a Faraday constant, f_{±} denotes an activity coefficient, t₊ denotes a cation transference number, Ye denotes a liquid-phase Bruggeman coefficient, and εₑ denotes a liquid-phase volume fraction.

The governing equation for mass conservation is as follows:

$$\frac{\partial {c}_{s}}{\partial t} + \frac{1}{{r}^{2}} \frac{\partial ( {r}^{2} J )}{\partial r} = 0 , \qquad ( 7 )$$

$${ε}_{e} \frac{\partial {c}_{e}}{\partial t} + ∇ \cdot ( - {D}_{e}^{eff} ∇ {c}_{e} ) = \frac{{S}_{a} {i}_{loc}}{F} ( 1 - {t}_{+} ) , \qquad ( 8 )$$

$${D}_{e}^{eff} = {D}_{e} {ε}_{e}^{{γ}_{e}} , \qquad ( 9 )$$

wherein, cₛ denotes a solid-phase concentration, r denotes a radial dimension of particles, J denotes a lithium-ion flux, Dₑ denotes a liquid-phase diffusion coefficient, and i_{loc} denotes a local current density.

The governing equation for electrode kinetics is as follows:

$${i}_{loc} = {i}_{0} ( exp ( \frac{{α}_{a} η F}{R T} ) - exp ( \frac{- {α}_{c} η F}{R T} ) ) , \qquad ( 10 )$$

$${i}_{0} = F k {c}_{s , surf}^{{α}_{c}} {{c}_{e}^{{α}_{a}} ( {c}_{s , m ax} - {c}_{s , s u r f} )}^{{α}_{a}} , \qquad ( 11 )$$

n=φₛ−φₑ−E_{eq}, (12)
wherein, η denotes an over-potential, i₀ denotes an exchange current density, k denotes a reaction rate constant, αₐ and α_{c} denote an anode/cathode transfer coefficient respectively, c_{s,surf} denotes a surface lithium-ion concentration, c_{s,max} denotes a maximum lithium-ion concentration, and E_{eq} denotes an equilibrium potential.

The governing equation for heat generation is as follows:

$${Q}_{ohm} = {σ}_{s}^{eff} ∇ {ϕ}_{s}^{2} + {σ}_{e}^{eff} ( ∇ {ϕ}_{e}^{2} + \frac{2 R T}{F} ( 1 + \frac{\partial ln {f}_{\pm }}{\partial ln {c}_{e}} ) ( 1 - {t}_{+} ) ∇ {c}_{e} ∇ {ϕ}_{e} ) , \qquad ( 13 )$$

Q_{act}=Sₐⁱ_{loc}(φₛ−φₑ−E_{eq}). (14)

$${Q}_{rea} = {S}_{a} {i}_{loc} T \frac{d {E}_{eq , ref}}{d T} , \qquad ( 15 )$$

Q_{tab}=l²R_{tab}, (16)
wherein, Qₒₕₘ denotes Ohmic heat, Q_{act} denotes activation heat, Qᵣₑₐ denotes reaction heat, Q_{tab} denotes tab generated heat, R_{tab} denotes a tab resistance, E_{eq} denotes an equilibrium potential, and E_{eq,ref} denotes an electrode equilibrium potential.

The boundary conditions are as follows:

$${σ}_{s}^{eff} \frac{\partial {ϕ}_{s}}{\partial x} {\vert}_{x = {L}_{n e g} + {L}_{s e p} + {L}_{p o s}} = - {i}_{a p p} , \qquad ( 17 )$$

$$\frac{\partial {ϕ}_{e}}{\partial x} {\vert}_{x = {L}_{n e g}} = \frac{\partial {ϕ}_{e}}{\partial x} {\vert}_{x = {L}_{n e g} + {L}_{s e p} + {L}_{p o s}} = 0 , \qquad ( 19 )$$

$$- \frac{\partial {c}_{s}}{\partial r} {\vert}_{r = 0} = 0 , \qquad ( 20 )$$

$$- {D}_{s} \frac{\partial {c}_{s}}{\partial r} {\vert}_{r = {R}_{p}} = \frac{{S}_{a} \times {i}_{loc}}{F} , \qquad ( 21 )$$

wherein, L_{neg} denotes the thickness of a negative electrode, Lₛₑₚ denotes the thickness of a separator, and Lₚₒₛ denotes the thickness of a positive electrode.

Further, the battery thermal model is constructed. As shown in FIG. 12, firstly, a three-dimensional geometric model of the battery is constructed based on the dimensions of the battery. The three-dimensional geometric model includes a battery core, an aluminum-plastic film, and tabs. Then, as shown in equation (22), the heat conduction, heat generation, and heat exchange processes of the battery are described based on an energy conservation equation.

$$ρ {C}_{p} \frac{d T}{d t} = ∇ ( λ ∇ T ) + {Q}_{g e n} + {Q}_{d i s} . \qquad ( 22 )$$

The heat exchange between the battery and the environment is described by the Newton's law of cooling, as shown in equation (23):

Q_{dis}=−hSₐ(T_{amb}−T), (23)
wherein, ρ denotes a density, Cₚ denotes a specific heat capacity, λ denotes a heat conductivity coefficient, Q_{dis} denotes dissipated heat, h denotes a convective heat coefficient, T_{amb} denotes an ambient temperature, and Q_{gen} denotes total generated heat.

As shown in FIG. 13, in the present example, the surface of the battery is divided into 12 sub-domains with different heat transfer coefficients. Each sub-domain corresponds to a different convective heat transfer coefficient, reflecting dynamic characteristics of heat exchange between different regions of the battery. This multi-domain thermal boundary condition modeling method can more accurately capture temperature asymmetry and non-uniformity during battery operation. The convective heat transfer coefficients of different sub-domains on the surface of the battery are shown in Table 3.

TABLE 3
Convective heat transfer coefficients corresponding to
different sub-domains on the surface of the battery

| Region | Parameter | Region | Parameter | Region | Parameter | Region | Parameter |
|---|---|---|---|---|---|---|---|
| 1 | h₁ = 25 | 2 | h₂ = 20 | 3 | h₃ = 20 | 4 | h₄ = 40 |
| 5 | h₅ = 25 | 6 | h₆ = 25 | 7 | h₇ = 25 | 8 | h₈ = 45 |
| 9 | h₉ = 40 | 10 | h₁₀ = 35 | 11 | h₁₁ = 35 | 12 | h₁₂ = 40 |

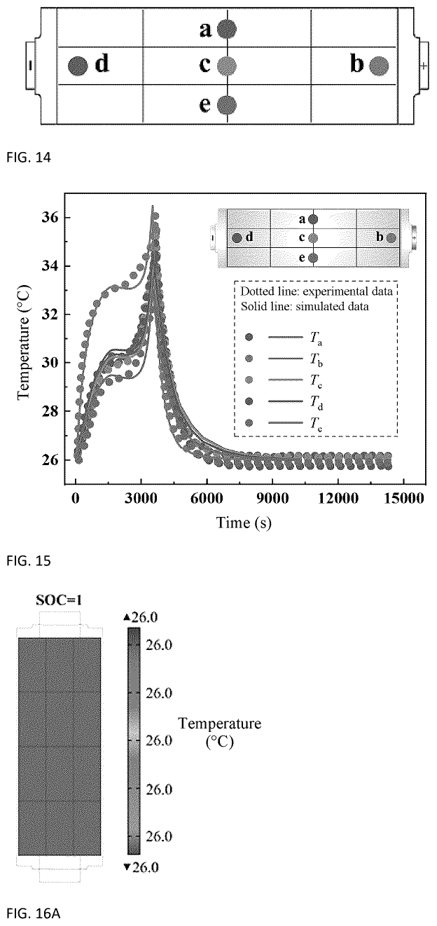

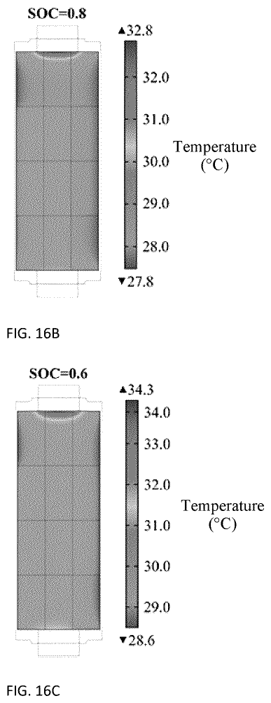

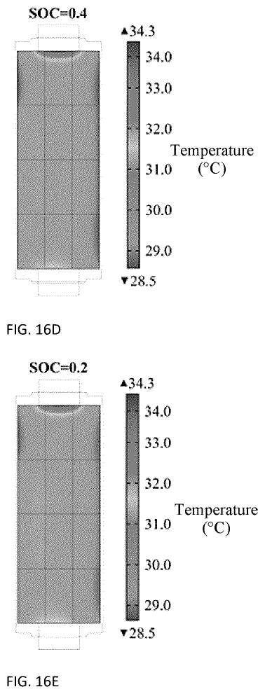

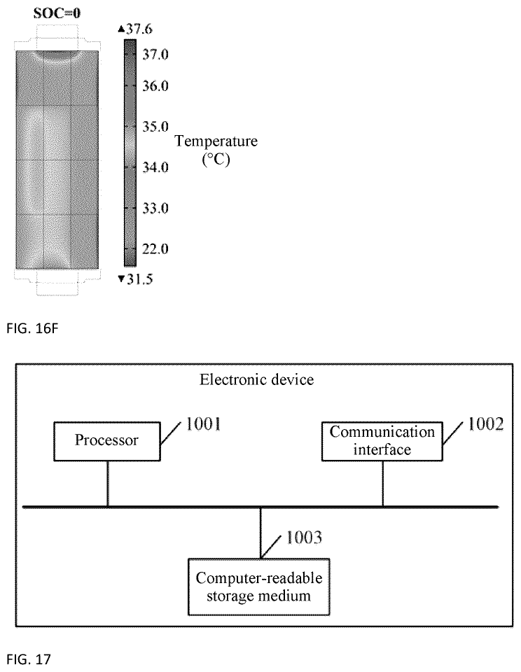

The convective heat transfer coefficients in the 12 regions are calibrated based on the temperature data monitored by the optical fiber. As shown in FIG. 14, in the present example, 5 representative points monitored by the optical fiber are used to calibrate the convective heat transfer coefficients. It should be noted that more points can be selected to calibrate the convective heat transfer coefficients according to the requirements for model accuracy. The present example uses the 5 representative points to demonstrate the effectiveness of the method provided by the present disclosure. FIG. 15 compares optical fiber monitored temperature curves and model predicted temperature curves of the 5 representative points during 1C discharging. It can be seen that the model results well coincide with the experimental data at all the five points. FIG. 16A to FIG. 16F show temperature distribution cloud maps predicted by the model in different SOCs, where FIG. 16A shows temperature distribution in a battery at SOC=1.0, FIG. 16B shows temperature distribution in a battery at SOC=0.8, FIG. 16C shows temperature distribution in a battery at SOC=0.6, FIG. 16D shows temperature distribution in a battery at SOC=0.4, FIG. 16E shows temperature distribution in a battery at SOC=0.2, and FIG. 16F shows temperature distribution in a battery at SOC=0. It can be seen that the model can well depict the non-uniform and asymmetric distribution of temperature during battery discharging in different SOCs. These results further demonstrate that the method provided by the present disclosure can effectively predict temperature distribution in the battery.

The method provided by the present disclosure considers variations in local thermal convection, thereby enabling prediction of the temperature distribution and local hotspots on the surface of the battery. This method can be embedded in a Battery Thermal Management System (BTMS) for real-time monitoring and control of battery thermal behaviors. Specifically, the BTMS can dynamically adjust the cooling strategy for each battery cell or a specific region based on the high-resolution temperature distribution cloud maps output by the model. Specifically, the BTMS can read physical values of the local hotspots from the output results of the temperature distribution cloud maps predicted by the model. When the read physical value of a local hotspot exceeds a preset threshold, the flow rate of a liquid coolant in a local hotspot region is increased, or the speeds of air-cooling fans at different positions on the battery are adjusted, thereby achieving regional differentiated thermal control.

In summary, compared to conventional integral cooling methods, this prediction-based locally responsive cooling strategy can significantly improve cooling efficiency, minimize energy consumption, maintain the uniformity of the temperature field of the battery pack, and effectively suppress the risk of thermal runaway caused by thermal gradients, thereby improving the safety and reliability of system operation.

### Example 3

A system for estimating temperature distribution in a battery, including:
a temperature obtaining module, configured to obtain distributed temperature data on
the surface of a battery, pre-process the temperature data, and perform spatial mapping on the pre-processed temperature data,
wherein the specific execution process of this module can refer to the process of step S1 in the Example 1, and will not be repeated here;
a coupled model constructing module, configured to construct an electrochemical model, determine heat sources, construct a geometric model based on morphological parameters of the battery, and couple the geometric model with the determined heat sources to form a battery thermal model,
where the specific execution process of this module can refer to the process of step S2 in the Example 1, and will not be repeated here; and
a temperature distribution estimating module, configured to perform domain division on the battery thermal model based on temperature gradient differences across different positions to form a plurality of sub-domains, calibrate convective heat transfer coefficients of different sub-domains based on spatial mapping results, and obtain temperature distribution estimation results on the surface of the battery based on the calibrated convective heat transfer coefficients,
where the specific execution process of this module can refer to the process of step S3 in the Example 1, and will not be repeated here.

It can be understood that the above units/modules can be separately or entirely merged into one or several other units/modules, or one (some) of the units can be further split into a plurality of smaller functional units, which can implement the same operations without affecting the technical effects of the embodiments of the present disclosure.

The above modules of this system are based on a logical functional division. In practical application, the function of one module can also be implemented by a plurality of modules, or the functions of a plurality of modules can be implemented by one module.

Similarly, in other examples of the present disclosure, the system may also include other units/modules. In practical application, these functions can also be implemented with the assistance of the other units and can be implemented by the collaboration of the plurality of units.

According to another example of the present disclosure, the system described in the present example can be constructed and the method of the Example 1 can be implemented by running a computer program (including program code) capable of executing the steps involved in the corresponding method described in the Example 1 on a general-purpose computing device such as a computer, which includes a storage element and processing elements such as a Central Processing Unit (CPU), a Random Access Memory (RAM), and a Read Only Memory (ROM). The computer program can be recorded on a computer-readable record medium, loaded onto the aforementioned computing device through the computer-readable record medium, and run therein.

### Example 4

A non-transitory computer-readable storage medium is provided for storing computer-readable instructions that, when executed by a processor, complete step S1 to step S3 of the method provided in the Example 1.

### Example 5

As shown in FIG. 17, an electronic device includes a processor 1001, a communication interface 1002, and a computer-readable storage medium 1003. The processor 1001, the communication interface 1002, and the computer-readable storage medium 1003 can be connected through a bus or other means.

The communication interface 1002 is used to receive and send data, the computer-readable storage medium 1003 can be stored in a memory of the electronic device, the computer-readable storage medium 1003 is used to store a computer program, the computer program includes computer-readable instructions, and the processor 1001 is used to execute the computer-readable instructions stored in the computer-readable storage medium 1003.

The processor 1001 (also known as CPU (Central Processing Unit)) is a computing core and control core of the electronic device, and is suitable for implementing one or more instructions, specifically for loading and executing one or more instructions to implement corresponding method flows or corresponding functions.

The processor 1001 is configured to perform the following process:
obtaining distributed temperature data on the surface of a battery, pre-processing the temperature data, and performing spatial mapping on the pre-processed temperature data;
constructing an electrochemical model, determining heat sources, constructing a geometric model based on morphological parameters of the battery, and coupling the geometric model with the determined heat sources to form a battery thermal model; and
performing domain division on the battery thermal model based on temperature gradient differences across different positions to form a plurality of sub-domains, calibrating convective heat transfer coefficients of different sub-domains based on the spatial mapping results, and obtaining temperature distribution estimation results on the surface of the battery based on the calibrated convective heat transfer coefficients.

### Example 6

A computer program product includes computer-readable instructions that, when executed by at least one data processing apparatus, enable the data processing apparatus to implement the steps of the method provided in the Example 1.

### Example 7

An electric vehicle includes a vehicle body, the vehicle body including a battery, distributed optical fiber sensors, and a battery management system, where
the battery is used to provide energy for the electric vehicle;
the distributed optical fiber sensors are used to obtain optical fiber data;
the battery management system is used to pre-process the optical fiber data, and perform spatial mapping on the pre-processed optical fiber data;
construct an electrochemical model, determine heat sources, construct a geometric model based on morphological parameters of the battery, and couple the geometric model with the determined heat sources to form a battery thermal model; and
perform domain division on the battery thermal model based on temperature gradient differences across different positions to form a plurality of sub-domains, calibrate convective heat transfer coefficients of different sub-domains based on the spatial mapping results, and obtain temperature distribution estimation results on the surface of the battery based on the calibrated convective heat transfer coefficients;
or, the battery management system includes the system for estimating temperature distribution in a battery provided in the Example 3;
or, the battery management system is loaded with the computer-readable storage medium provided in the Example 4 or the computer program product provided in the Example 6;
or, the battery management system includes the electronic device provided in the Example 5.

Described above are merely preferred embodiments of the present disclosure, and the present disclosure is not limited thereto. For those skilled in the art, various modifications and variations can be made to the present disclosure. Any modifications, equivalent substitutions, improvements, etc. made by those skilled in the art without any creative efforts within the spirit and principles of the present disclosure shall fall within the scope of protection of the present disclosure.

1. A method for estimating temperature distribution in a battery, comprising:
obtaining distributed temperature data on the surface of a battery, pre-processing the temperature data, and performing spatial mapping on the pre-processed temperature data;
constructing an electrochemical model, determining heat sources, constructing a geometric model based on morphological parameters of the battery, and coupling the geometric model with the determined heat sources to form a battery thermal model; and
performing domain division on the battery thermal model based on temperature gradient differences to form a plurality of sub-domains, calibrating convective heat transfer coefficients of different sub-domains based on the spatial mapping results, and obtaining temperature distribution estimation results on the surface of the battery based on the calibrated convective heat transfer coefficients;
wherein, in the process of obtaining distributed temperature data on the surface of a battery, optical fiber data is obtained by using distributed optical fiber sensors, wherein the distributed optical fiber sensors are arranged on the surface of the battery in a reciprocating manner, or at intervals in a helical pattern, or at intervals in a grid pattern, and
the distributed optical fiber sensors are provided within designated positive and negative electrode regions of the battery, or/and within a designated central region of the battery;
wherein, the process of performing spatial mapping on the pre-processed optical fiber data comprises: dividing an arrangement path of an optical fiber into a plurality of segments, wherein each segment is a straight segment or an arc segment, and end points and/or center points of the segments are used as feature points to calibrate key positions of the path of the optical fiber;
for the straight segment, uniformly mapping all optical fiber data within the straight segment onto the straight segment by using an interpolation algorithm; and
for the arc segment, determining a center angle and radius of the arc segment, calculating distribution of the optical fiber within the arc segment by using an arc length formula, and uniformly mapping all optical fiber data within the arc segment onto the corresponding arc path on the surface of the battery according to an arc length proportion by using the interpolation algorithm;
wherein, the process of constructing an electrochemical model comprises:
a process of performing spatial mapping on the pre-processed optical fiber data, comprising:
when the distributed optical fiber sensors are arranged in the helical pattern, determining basic parameters of the helix, comprising a radius of a projection circle of the helix on a horizontal plane, a pitch, and a total length of the helix; calculating parameter equations of the helix, calculating an arc length of the helix by integration, then determining an arc length corresponding to each data point, and performing reverse calculation to determine three-dimensional coordinates of the data point on the helix; and
a process of calibrating convective heat transfer coefficients of different sub-domains based on the spatial mapping results, comprising: comparing temperature data obtained from the optical fiber data of different sub-domains with calculation results of the battery thermal model, and adjusting and optimizing the convective heat transfer coefficients of the corresponding sub-domains based on the differences.

2. The method for estimating the temperature distribution in the battery according to claim 1,
wherein the pre-processing process comprises: converting wavelength data of the optical fiber into temperature data based on a relationship between a frequency shift induced by Rayleigh scattering and temperature; and
comparing the converted temperature data with temperature data detected by a temperature sensor at a corresponding position to obtain an accurate wavelength-temperature relationship equation, and calibrating the converted temperature data.

3. The method for estimating the temperature distribution in the battery according to claim 1,
wherein the process of constructing an electrochemical model comprises: selecting to construct a one-dimensional, two-dimensional, or three-dimensional electrochemical model according to an actual usage scenario and performance requirements of the battery, wherein the electrochemical model is used to calculate heat generated by the battery during charging and discharging, and the generated heat comprises Ohmic heat, activation heat, reaction heat, and tab generated heat.

4. The method for estimating the temperature distribution in the battery according to claim 1,
wherein the process of constructing a geometric model based on morphological parameters of the battery comprises: constructing the geometric model of the battery by three-dimensional modeling based on the actual dimensions and morphology of the battery, wherein the geometric model is used to reflect the external dimensions, internal structure, and surface morphological characteristics of the battery.

5. The method for estimating the temperature distribution in the battery according to claim 1,
wherein the process of performing domain division on the battery thermal model based on temperature gradient differences to form a plurality of sub-domains comprises: dividing the surface of the battery into the plurality of sub-domains based on the horizontal and vertical temperature gradients on the surface of the battery and the requirements for model accuracy, wherein each sub-domain corresponds to a different convective heat transfer coefficient to reflect dynamic characteristics of heat exchange between different regions of the battery, and the heat exchange between each sub-domain and the environment is individually configurable.

6. The method for estimating the temperature distribution in the battery according to claim 1,
wherein the process of calibrating convective heat transfer coefficients of different sub-domains comprises: simulating a cooling process by using the battery thermal model based on temperature variations across the battery recorded by the distributed optical fiber sensors, and determining initial values of the convective heat transfer coefficients by matching experimental temperature decay curves; and
performing iterative optimization by taking minimization of a squared difference between the temperature distribution predicted by the model and the obtained true value as an objective function to adjust the convective heat transfer coefficients until the temperature distribution predicted by the model converges within a preset threshold.

7. A system for estimating temperature distribution in a battery, comprising:
a temperature obtaining module, configured to obtain distributed temperature data on the surface of a battery, pre-process the temperature data, and perform spatial mapping on the pre-processed temperature data;
a coupled model constructing module, configured to construct an electrochemical model, determine heat sources, construct a geometric model based on morphological parameters of the battery, and couple the geometric model with the determined heat sources to form a battery thermal model; and
a temperature distribution estimating module, configured to perform domain division on the battery thermal model based on temperature gradient differences to form a plurality of sub-domains, calibrate convective heat transfer coefficients of different sub-domains based on spatial mapping results, and obtain temperature distribution estimation results on the surface of the battery based on the calibrated convective heat transfer coefficients;
wherein, in the process of obtaining distributed temperature data on the surface of a battery, optical fiber data is obtained by using distributed optical fiber sensors, the distributed optical fiber sensors are arranged on the surface of the battery in a reciprocating manner, or at intervals in a helical pattern, or at intervals in a grid pattern, and
the distributed optical fiber sensors are provided within designated positive and negative electrode regions of the battery, or/and within a designated central region of the battery;
wherein, the process of performing spatial mapping on the pre-processed optical fiber data comprises: dividing an arrangement path of an optical fiber into a plurality of segments, wherein each segment is a straight segment or an arc segment, and end points and/or center points of the segments are used as feature points to calibrate key positions of the path of the optical fiber;
for the straight segment, uniformly mapping all optical fiber data within the straight segment onto the straight segment by using an interpolation algorithm; and
for the arc segment, determining a center angle and radius of the arc segment, calculating distribution of the optical fiber within the arc segment by using an arc length formula, and uniformly mapping all optical fiber data within the arc segment onto the corresponding arc path on the surface of the battery according to an arc length proportion by using the interpolation algorithm;
wherein, the process of constructing an electrochemical model comprises:
a process of performing spatial mapping on the pre-processed optical fiber data, comprising:
when the distributed optical fiber sensors are arranged in the helical pattern, determining basic parameters of the helix, comprising a radius of a projection circle of the helix on a horizontal plane, a pitch, and a total length of the helix; calculating parameter equations of the helix, calculating an arc length of the helix by integration, then determining an arc length corresponding to each data point, and performing reverse calculation to determine three-dimensional coordinates of the data point on the helix; and
a process of calibrating convective heat transfer coefficients of different sub-domains based on the spatial mapping results, comprising: comparing temperature data obtained from the optical fiber data of different sub-domains with calculation results of the battery thermal model, and adjusting and optimizing the convective heat transfer coefficients of the corresponding sub-domains based on the differences.

8. A computer-readable storage medium, used for storing computer-readable instructions that, when executed by a processor, complete the steps of the method according to claim 1.

9. An electronic device, comprising a memory, a processor, and computer-readable instructions stored on the memory and executed on the processor, wherein the computer-readable instructions, when executed by the processor, complete the steps of the method according to claim 1.

10. A computer program product, comprising computer-readable instructions that, when executed by at least one data processing apparatus, enable the data processing apparatus to implement the steps of the method according to claim 1.

11. An electric vehicle, comprising a vehicle body, the vehicle body comprising a battery, distributed optical fiber sensors, and a battery management system, wherein:
the battery is used to provide energy for the electric vehicle;
the distributed optical fiber sensors are used to obtain optical fiber data; and
the battery management system comprises the system for estimating temperature distribution in a battery according to claim 7.
